(19) United States
(12) Patent Application Publication
(10) Pub. No.: US 2008/0297972 A1
(43) Pub. Date: Dec. 4, 2008

(54) Capacitor structure with variable capacitance, and use of said capacitor structure

(75) Inventor: Richard Matz, Bruckmnhl (DE)

Correspondence Address: STAAS & HALSEY LLP, SUITE 700, 1201 NEW YORK AVENUE, N.W., WASHINGTON, DC, 20005, US

(73) Assignee: Siemens Aktiengesellschaft, Munich (DE)

(21) Appl. No.: 12/007,263

(22) Filed: Jan. 8, 2008

(30) Foreign Application Priority Data
May 29, 2007 (DE) 10 2007 024 901.4

(51) Int. Cl. H01G 5/01; H03L 7/099; H04B 1/10; H03H 7/38

(52) U.S. Cl. 361/277; 331/177 R; 327/557; 333/32

(57) ABSTRACT

A capacitor structure with variable capacitance, has at least one capacitor. More specifically, the structure has a capacitor electrode, a capacitor counter-electrode arranged opposite said capacitor electrodes at a variable capacitor electrode distance in relation hereto and at least one actuator for varying the capacitor electrode distance, and an actuator electrode for electrically controlling the actuator by which the variation in the capacitor electrode distance is effected. The the actuator electrode and one of the capacitor electrodes of the capacitor are arranged next to one another on a common carrier. Advantageously, the actuator electrode and the capacitor electrode arranged next to said actuator electrode are electrically isolated from one another. By this, the control circuit and function circuit are decoupled. Advantageously, the actuator is a piezoceramic bending transducer. The capacitor structure is deployed for example in a voltage-controlled oscillator (VCO). The capacitor structure is used in particular in communications technology and mobile radio technology. The capacitor structure provides a basic element of the “software defined radio” (SDR) concept.

### CROSS REFERENCE TO RELATED APPLICATIONS

This application is based on and hereby claims priority to German Application No. 10 2007 024 901.4 filed on May 29, 2007, the contents of which are hereby incorporated by reference.

### BACKGROUND

The invention relates to a capacitor structure with variable capacitance, having at least one capacitor comprising at least one capacitor electrode, at least one capacitor counter-electrode arranged opposite said capacitor electrode at a variable capacitor electrode distance therefrom and at least one actuator for varying the capacitor electrode distance,

A capacitor structure with high-quality variable capacitance (tunable capacitance) is needed, for example, for a voltage-controlled oscillator, VCO. A circuit of this type is used as a generator of reference frequencies and for mixing channel frequencies and carrier frequencies in communications technology. For maximum possible frequency stability, high-quality low-loss capacitors are required which will at the same time, however, be widely tunable. Besides the application stated, tunable capacitances are also used for tunable filters in high-frequency and microwave technology. A frequency filter of this type is, for example, a bandpass filter. The bandpass filter is permeable to a high-frequency signal within a defined frequency band (pass band). This means that a damping factor for a high-frequency signal within this frequency band is low.

A capacitor structure of the type stated in the introduction is known from WO 2005/059932 A1. The actuator is, for example, a piezoceramic bending transducer. The bending transducer can be fashioned as a so-called bimorph. In a bending transducer of this type, a piezoelement, formed of a piezoelectrically active ceramic layer and electrode layers attached on both sides (actuator electrodes), is rigidly connected to a piezoelectrically inactive layer. Electrical control of the electrode layers of the piezoelement of the bending transducer produces deflection of the piezoelectrically active ceramic layer. The piezoelectrically inactive layer, on the other hand, is not deflected by control of the electrode layers of the piezoelement. Due to the rigid connection between the layers, the result is a bending of the bending transducer.

One of the actuator electrodes of the piezoelement functions simultaneously as a capacitor electrode. As a consequence of the bending of the bending transducer, the capacitor electrode distance between the capacitor electrode and the capacitor counter-electrode varies. The capacitance of the capacitor varies. A capacitor of this type is also called a varactor.

The current which is controllable via the capacitor with variable capacitance is dependent on the mode of operation of the actuator. Because of the bending of the bending transducer that has to be achieved, the capacitor electrode or the actuator electrode is very thin. This gives rise to a relatively low current-carrying capacity, so the current which is controllable with the aid of the variable capacitance is limited.

### SUMMARY

One potential object is to describe a compact capacitor structure with variable capacitance, in which the current controllable by the variable capacitance is largely independent of the mode of operation of the actuator for adjusting the capacitor electrode distance.

The inventor proposes a capacitor structure with variable capacitance, having at least one capacitor comprising at least one capacitor electrode, at least one capacitor counter-electrode arranged opposite said capacitor electrode at a variable distance therefrom and at least one actuator for varying the capacitor electrode distance, having at least one actuator electrode for electrically controlling the actuator by which the variation of the capacitor electrode distance is effected. The capacitor structure is characterized in that the actuator electrode and one of the capacitor electrodes of the capacitor are arranged next to one another on a common carrier.

The actuator serves as a final control element for adjusting the capacitor electrode distance. The actuator electrode and the capacitor electrode or the capacitor counter-electrode are arranged on a common surface section of the carrier. The carrier is an integral component of the actuator.

In a particular embodiment, the common carrier is an actuator-function layer of the actuator. The actuator-function layer contributes to the mode of operation of the actuator. For example, the actuator is a bimetal (thermobimetal) actuator. An actuator of this type includes, for example, of two rigidly connected metal strips composed of metals having different thermal expansion coefficients. Electrical control of the adjacent actuator electrode results in heating of the adjacent actuator-function layers, which are possibly electrically insulated from the actuator electrode, and, as a consequence of the heating, in bending of the actuator. It is also conceivable for the actuator-function layer to comprise magnetostrictive material. Through control of the actuator electrode, a magnetic field couples into this actuator-function layer. The Weiss domains of the magnetostrictive material align themselves. As a result, a change in the expansion of the actuator-function layer is produced. If this actuator-function layer is now rigidly connected to an actuator-function layer formed of a non-magnetic material, a bending of the actuator is produced. Since one of the actuator-function layers is simultaneously the carrier of one of the capacitor electrodes, actuation and adjustability of capacitance are linked to one another in a simple manner.

As previously indicated in the description of the actuator-function layer, the actuator can operate thermally or magnetostrictively. In a particular embodiment, the actuator is a piezoelectric actuator. The piezoelectric actuator has at least one piezoelement. The piezoelement comprises a piezoelectric layer and electrode layers (actuator electrodes) arranged on both sides. Through electric control of the actuator electrodes, an electric field is coupled into the piezoelectric layer. A change in expansion in the piezoelectric layer is produced and, due to the change of expansion, an actuating effect of the actuator.

The embodiment of the piezoelectric actuator is arbitrary. What is crucial is that the piezoelectrically induced deflection of the actuator is sufficiently large that a desired change in the distance between the capacitor electrodes can be achieved. In order to achieve a relatively large deflection, a piezoelectric actuator can be used which has a plurality of piezoelements stacked on top of one another to form an actuator body. The piezoelements can be bonded together. This is a solution, for example, for piezoelements with piezoelectric layers formed of a piezoelectric polymer such as polyvinylidene difluoride (PVDF). Piezoelectric layers composed of a piezoceramic material are also conceivable. The piezoceramic material is, for example, a lead zirconate titanate (PZT) or a zinc oxide (ZnO). The piezoelements comprising piezoelectric layers formed of piezoceramic material are not, for example, bonded together but are connected in a common sintering process to form an actuator body with a monolithic multilayer structure.

In a particular embodiment, the piezoelectric actuator is a piezoelectric bending transducer. By a relatively small control voltage, a relatively large deflection in the bending transducer can be achieved. Thus, for example, a control voltage of under 10 V is sufficient to produce a deflection of the bending transducer of over 10 μm. By virtue of the large deflection that is achievable, the distance between capacitor electrode and capacitor counter-electrode can be varied over a wide range. In this way, it is possible to vary the capacitance of the capacitor over a wide range.

The bending transducer can, as described in the introduction, be fashioned as a bimorph. The actuator-function layer can be a piezoelectrically active or piezoelectrically inactive layer. Both layers contribute to the mode of operation of the bimorph. The piezoelectric layer is preferably directly the actuator-function layer. The piezoelectric layer is dielectric. No additional electrical insulation has to be provided.

As an alternative to the bimorph, a bending transducer in the form of a multimorph, which has a plurality of piezoelectrically active layers that are rigidly connected to one another, is also conceivable. The piezoelectrically active layers can be combined to form a single piezoelement. The piezoelectrically active layers, stacked on top of one another as partial layers, together form the complete piezoelectric layer of the piezoelement. It is also conceivable for a plurality of piezoelements each having a piezoelectrically active layer to be arranged to form a multilayer compound. Through control of the electrode layers of the piezoelement(s) of the bending transducer, different electric fields are coupled into the piezoelectrically active layers, leading to different deflections of the piezoelectrically active layers. In this case, too, the result is a bending of the bending transducer.

The capacitance of the capacitor can be varied over a wide range solely by changing the distance from the capacitor electrode to the capacitor counter-electrode. In order to increase this range, in a particular embodiment, a dielectric material with a relative dielectric constant of over 10 can be arranged within the spacing between the capacitor electrode and the capacitor counter-electrode. Preferably, a dielectric material with a relative dielectric constant of over 50 is used. This dielectric material is termed a highly dielectric material.

The dielectric material is arranged such that the electric field which is generated by control of the capacitor electrode and of the capacitor counter-electrode can be coupled into the dielectric material. To do this, the dielectric layer is applied immediately and directly onto the capacitor electrode or the capacitor counter-electrode. It is also conceivable for a dielectric layer to be applied onto each of the two capacitor electrodes.

The capacitor and the actuator are preferably arranged on a common carrier body (substrate). To protect the capacitor against environmental influences, a cover can be provided.

The carrier body and/or the cover are preferably selected from the category of semiconductor body, organic multilayer body and/or ceramic multilayer body. The carrier body and/or the cover comprise a semiconductor material, an organic material or a ceramic material. The semiconductor body is, for example, a silicon substrate. The ceramic body is, for example, a ceramic substrate composed of aluminum oxide. A plurality of passive electrical devices can be integrated inside a multilayer body. The multilayer body can be an organic multilayer body (multilayer organic, MLO) or a ceramic multilayer body (multilayer co-fired ceramic, MLCC). An LTCC (low temperature co-fired ceramic), in which, due to a low densification temperature of the ceramic, metals that have low melting points and are electrically highly conductive such as silver and copper can be used for integrating the passive components, is particularly possible as a ceramic multilayer body. HTCC (high temperature co-fired ceramic) substrates are also conceivable.

In a particular embodiment, a current-carrying capacity of the actuator electrode is less than a current-carrying capacity of the capacitor electrode arranged on the carrier. This is achieved, for example, in that, where the same electrode material is used for the capacitor electrode and the actuator electrode, a layer thickness of the capacitor electrode is greater than a layer thickness of the actuator electrode. The difference may correspond to a factor of between 10 and 100. A result of this is that, due to the thin actuator electrode, the deflectability of the actuator is scarcely affected. At the same time, a high current-carrying capacity of the capacitor electrode is provided. With the aid of the capacitor structure, a high current can be switched.

The actuator electrode and the capacitor electrode arranged next to said actuator electrode can be electrically connected to one another. The electrodes are not galvanically separated from one another. However, it is particularly advantageous if the actuator electrode and the capacitor electrode arranged on the carrier are arranged at a carrier electrode distance from one another and are galvanically separated from one another. Due to the carrier electrode distance, the electrodes are electrically insulated from one another. A control circuit for controlling the actuator with direct voltage and a function circuit (high-frequency alternating voltage in the GHz range) with variable capacitance are electrically insulated from one another.

To tap the variable capacitance, a serial configuration of two capacitors can be particularly favorable. It is advantageous here if the two capacitors each have a variable capacitance. A disadvantage that has to be incurred as a result, namely the reduction in the absolute capacitance of the series-connected capacitors, can be compensated for in a simple manner by enlarging the capacitor electrode surfaces.

In a particular embodiment, a spacer element is arranged on the carrier inside the carrier electrode distance. Various functions can be associated with the spacer element. The spacer element can simply contribute to improving the electrical insulation of the capacitor electrode and of the actuator electrode. Any “cross-talk” between control circuit and function circuit is suppressed. This works successfully, for example, due to the fact that the spacer element is composed of electrically insulating material. Advantageously, the spacer element also comprises a ceramic material, since with this material a second possible function of the spacer element can be implemented: a mass of the bending transducer (bending beam) is increased by the spacer element. Through the increase in mass, the inertia of the bending beam is increased. As a consequence of the increased inertia of the bending beam, a stability in the transmission of high-frequency signals improves and consequently a linearity of the component. In addition, it is particularly advantageous if the spacer element is a ceramic multilayer component. A ceramic multilayer component is described in connection with the substrate (see above). It is particularly advantageous to integrate at least one electrical device in the multilayer component. The result is a compact, space-saving design. Furthermore, by integrating the device in the spacer element, an electrical shielding of control circuit and function circuit can be achieved.

The spacer element can be arranged next to the capacitor electrode. It is particularly advantageous to arrange the capacitor electrode on the spacer element. The result is an ideal link between the insulating effect of the spacer element and the facility to integrate further functions and the increase in mass of the bending beam associated with the spacer element.

The described capacitor structure with variable capacitance is used in particular in tunable oscillators. With the aid of the capacitor structure, an adjustment of a voltage-controlled oscillator circuit is carried out. The tunable oscillators are used in, among other things, high-frequency and microwave technology.

Preferably, the capacitor structure is also used for adjusting a frequency band of a frequency filter. The possibility of being able to vary a frequency band of a frequency filter over a wide range by electrical control of the capacitor structure makes it possible to implement with the aid of the proposed device a communications and mobile radio concept termed “software defined radio (SDR). The aims of SDR is to implement not discrete frequency bands but arbitrarily (continuously) variable frequency bands for communications and mobile radio technology. The tunable proposed capacitor provides a basic building block for the implementation of SDR.

Preferably, the capacitor structure is also used for adjusting the impedance of a matching circuit. Impedance matching is necessary to prevent signal reflections between circuit elements, for example at the input and output of a power amplifier. It is usually implemented by appropriately combined passive components, in particular coils and capacitors. The function is thus limited to a finite frequency interval. When the operating frequency of a circuit is shifted, for example by changing a filter setting, the impedance matching therefore also has to be tuned to the new frequency band.

To summarize, the following advantages can be highlighted:
A capacitor structure is provided, with capacitors whose capacitances can be varied over a wide range and to a high quality standard.
The currents which can be switched through the variable capacitances do not depend on a mode of operation of the actuator used.
Through the use of a spacer element, control circuit and function circuit are decoupled from one another.
Through the use of multilayer technology, a plurality of functionalities can be integrated in the spacer element and in the substrate of the capacitor structure.
With the aid of the capacitor structure, a key building block of the SDR concept is provided.

### BRIEF DESCRIPTION OF THE DRAWINGS

These and other objects and advantages of the present invention will become more apparent and more readily appreciated from the following description of the preferred embodiments, taken in conjunction with the accompanying drawings of which:

FIGS. 1 to 3 each show an exemplary embodiment of a tunable capacitor arrangement in a lateral cross-section.

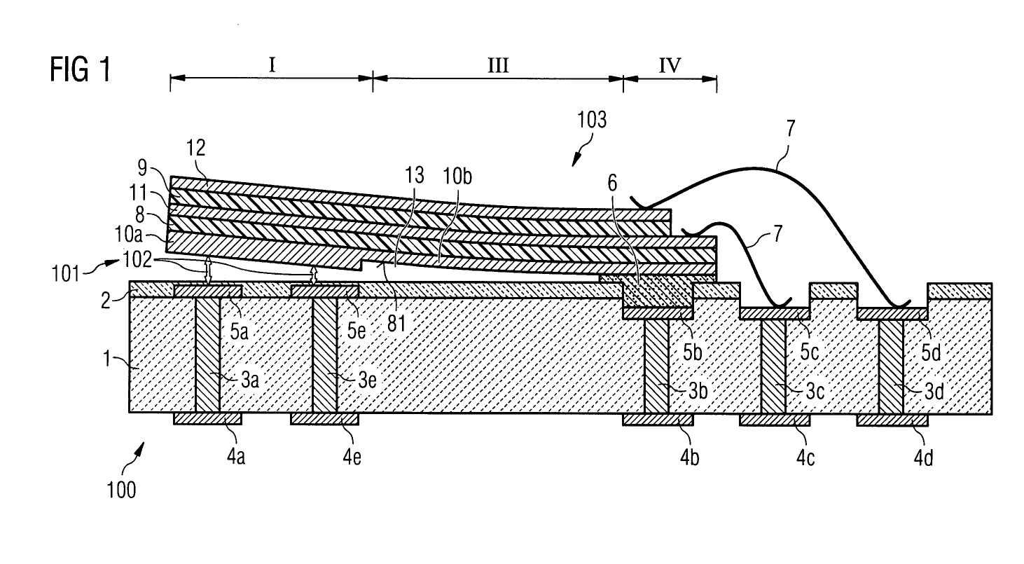

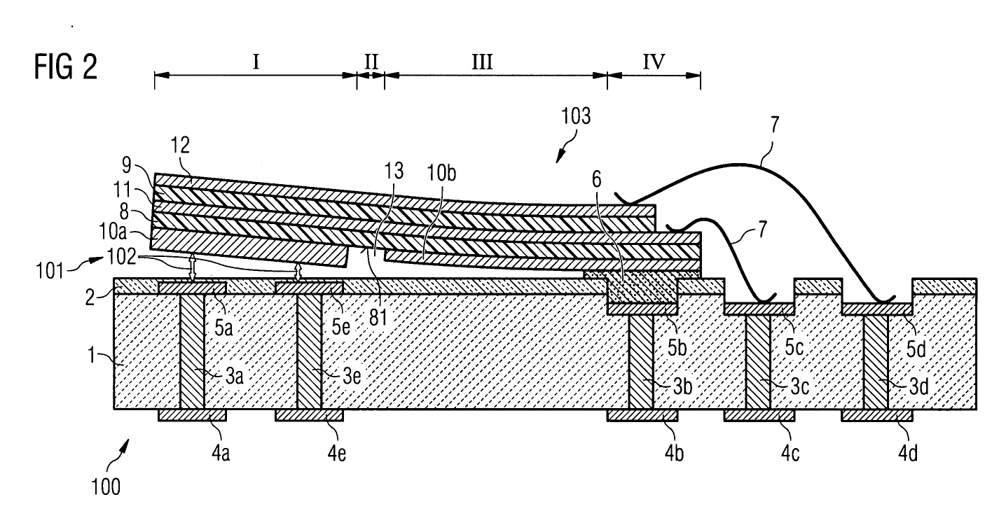

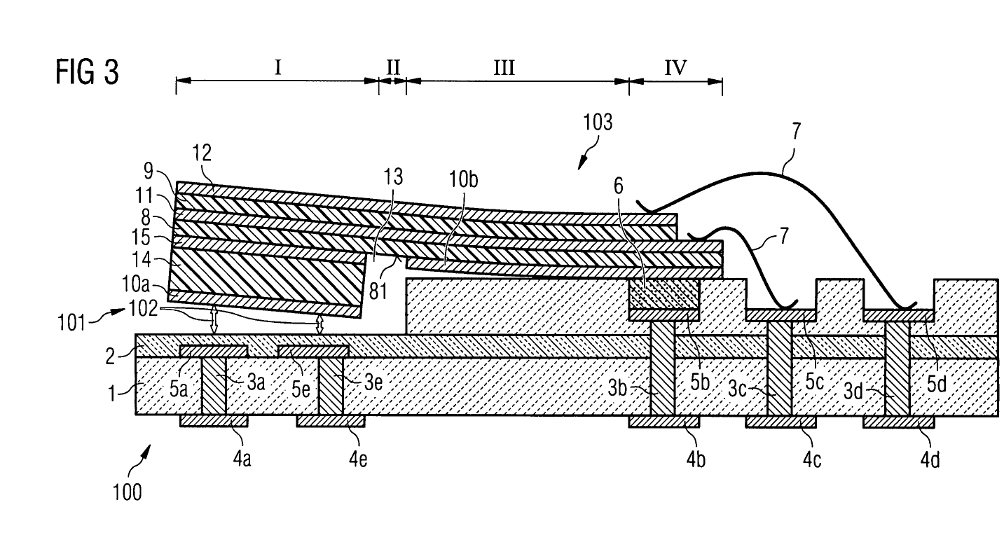

### DETAILED DESCRIPTION OF THE PREFERRED EMBODIMENT

Reference will now be made in detail to the preferred embodiments of the present invention, examples of which are illustrated in the accompanying drawings, wherein like reference numerals refer to like elements throughout.

The exemplary embodiments each relate to a capacitor structure 100 with variable capacitances, having two series-connected capacitors 101, each comprising a capacitor electrode 5a, 5e and a capacitor counter-electrode 10a arranged opposite said capacitor electrodes at a variable capacitor electrode distance 102 therefrom.

To vary the capacitor electrode distance, an actuator is provided in the form of a piezoceramic bending transducer 103. The piezoceramic bending transducer has a bending beam fashioned as a multimorph. The bending beam includes two piezoceramic layers (actuator-function layers) 8 and 9, which are equipped with metallizations 10b, 11 and 12. These metallizations form the actuator electrodes, through whose electrical control electric fields are coupled into the piezoceramic layers. This results in a bending of the bending transducer. The bending produces the change in the respective capacitor electrode distance of the two capacitors.

The actuator electrode 10b and the capacitor counter-electrode 10a are arranged next to one another on a common surface section 81 of the piezoceramic layer 8. The piezoceramic layer 8 is the carrier of the two electrodes 10a and 10b.

The bending beam is applied onto a ceramic multilayer substrate 1. According to a first embodiment, the multilayer substrate is an LTCC substrate. In a further embodiment, the multilayer substrate is an HTCC substrate.

Located on the substrate is a thin highly dielectric layer 2. This layer covers the substrate and the capacitor electrodes 5a and 5e. There are located in the substrate electrical through-plated holes 3a, 3b, 3c, 3d, 3e which terminate on the underside and top of the substrate in contact areas 4a, 4b, 4c, 4d, 4e and 5a, 5b, 5c, 5d, 5e respectively. The contact areas 5a and 5e are the capacitor electrodes of the two capacitors.

With the aid of an electrically conductive adhesive 6, the lower actuator electrode 10b of the bending beam is secured to the substrate and bonded. The actuator electrodes 11 and 12 are electrically connected via wire bonds 7 to the contact areas 5c and 5d. When operating, the contacts 4b and 4d are set to ground potential or to the maximum direct voltage, for example, 200 V. With a control voltage that can be varied between ground potential and maximum voltage, the bending transducer can be moved up and down. The neutral horizontal position of the bending transducer corresponds to half the maximum voltage, as here the two piezoelectric layers 8 and 9 are equally tensioned. The variable capacitances are fashioned on the basis of the variable air gap at the free end of the bending beam between the capacitor electrode 5a and the capacitor counter-electrode 10a or between the capacitor electrode 5e and the capacitor counter-electrode 10a. The variable capacitances take effect in circuit-engineering terms at the contacts 4a and 4e. The highly dielectric layer 2 gives rise to high capacitances when the bending beam is in a horizontal position. The respective air gap leads to a steep reduction in capacitance with increasing overload.

### EXAMPLE 1

According to the first example, the capacitor counter-electrode 10a and actuator electrode 10b are electrically connected to one another, i.e. not galvanically separated. However, the capacitor counter-electrode has a substantially higher current-carrying capacity than the actuator electrode. This is produced by the greater layer thickness of the capacitor counter-electrode compared with the actuator electrode (if the electrode material is the same). The bending transducer can be subdivided into three areas I, II and IV. Area I contributes substantially to the tunable capacitances. Area III designates the bending function of the bending transducer. Since the capacitor counter-electrode 10a and the actuator electrode 10b are not galvanically separated from one another, control circuit and function circuit are coupled to one another.

### EXAMPLE 2

The capacitor counter-electrode 10a and the actuator electrode 10b are galvanically separated from one another. The two electrodes are arranged on the common surface section of the carrier at a carrier electrode distance 13 from one another. The metallization applied to the underside of the piezoceramic layer 8 is interrupted. As a result of the interruption, the functional sections labeled I to IV can be distinguished along the bending transducer: section I with the metallization 10a is a component part of the capacitors with variable capacitances. However, as a result of the interruption 13, this component part plays only an incomplete role in the mechanical bending. II designates the interruption between the capacitor electrode 10a and the actuator electrode 10b. III marks the active bending area of the bending transducer. The area of the electrical bonding of metallizations and the mechanical connection of the bending beam to the substrate is designated IV.

### EXAMPLE 3

In contrast to the preceding example, a spacer element 14 is additionally present in the carrier electrode distance 13. The capacitor counter-electrode 10a is arranged on the spacer element. To connect the spacer element to the bending beam, an additional metallization 15 is provided. The spacer element is a ceramic multilayer component, inside which electrical devices are integrated. The ceramic multilayer component is produced according to a first embodiment using LTCC technology and according to a further embodiment using HTCC technology. Here, too, the capacitance structure can be subdivided into areas I to IV.

The tunable capacitor structures described are used for adjusting a frequency band of a frequency filter or for adjusting a voltage-controlled oscillator circuit.

The invention has been described in detail with particular reference to preferred embodiments thereof and examples, but it will be understood that variations and modifications can be effected within the spirit and scope of the invention covered by the claims which may include the phrase “at least one of A, B and C” as an alternative expression that means one or more of A, B and C may be used, contrary to the holding in Superguide v. DIRECTV, 69 USPQ2d 1865 (Fed. Cir. 2004).

1-15. (canceled)

16. A capacitor structure with variable capacitance, having at least one capacitor, comprising;
a capacitor electrode;
a capacitor counter-electrode arranged opposite said capacitor electrode at a variable capacitor electrode distance; and
an actuator to vary the capacitor electrode distance, the actuator having an actuator electrode for electrically controlling the actuator and varying the capacitor electrode distance, the actuator electrode being positioned next to an adjacent electrode on a common carrier, the adjacent electrode being the capacitor electrode or the capacitor counter-electrode.

17. The capacitor structure as claimed in claim 16, wherein the common carrier serves as an actuator-function layer of the actuator.

18. The capacitor structure as claimed in claim 16, wherein the actuator is a piezoelectric actuator.

19. The capacitor structure as claimed in claim 18, wherein the common carrier serves as an actuator-function layer of the actuator, and the actuator-function layer is a piezoelectric layer of the piezoelectric actuator.

20. The capacitor structure as claimed in claim 18, wherein the piezoelectric actuator is a bending transducer.

21. The capacitor structure as claimed in claim 16, wherein a current-carrying capacity of the actuator electrode is less than a current-carrying capacity of the adjacent electrode positioned next to the actuator electrode on the common carrier.

22. The capacitor structure as claimed in claim 16, wherein
the actuator electrode and the adjacent electrode on the carrier are arranged at a carrier electrode distance from one another, and
the actuator electrode and the adjacent electrode are galvanically separated from one another.

23. The capacitor structure as claimed in claim 22, wherein
a spacer element is arranged on the common carrier, and
the spacer element is separated from the actuator electrode by at least the carrier electrode distance.

24. The capacitor structure as claimed in claim 23, wherein the adjacent electrode is positioned on the spacer element.

25. The capacitor structure as claimed in claim 23, wherein the spacer element comprises ceramic material.

26. The capacitor structure as claimed in claim 25, wherein the spacer element is a ceramic multilayer component.

27. The capacitor structure as claimed in claim 26, wherein at least one electrical device is integrated in the ceramic multilayer component.

28. The capacitor structure as claimed in claim 16 wherein the actuator electrode does not function as either the capacitor electrode or the capacitor counter electrode.

29. The capacitor structure as claimed in claim 19, wherein the piezoelectric actuator is a bending transducer.

30. The capacitor structure as claimed in claim 29, wherein a current-carrying capacity of the actuator electrode is less than a current-carrying capacity of the adjacent electrode positioned next to the actuator electrode on the common carrier.

31. The capacitor structure as claimed in claim 30, wherein
the actuator electrode and the adjacent electrode on the carrier are arranged at a carrier electrode distance from one another, and
the actuator electrode and the adjacent electrode are galvanically separated from one another.

32. The capacitor structure as claimed in claim 31, wherein
a spacer element is arranged on the common carrier, and
the spacer element is separated from the actuator electrode by at least the carrier electrode distance.

33. A method for adjusting a frequency band, comprising:
providing a frequency filter comprising:
a capacitor electrode;
a capacitor counter-electrode arranged opposite said capacitor electrode at a variable capacitor electrode distance; and
an actuator to vary the capacitor electrode distance, the actuator having an actuator electrode, the actuator electrode being positioned next to an adjacent electrode on a common carrier, the adjacent electrode being the capacitor electrode or the capacitor counter-electrode; and
electrically controlling the actuator electrode to vary the capacitor electrode distance.

34. A method for adjusting an oscillator, comprising:
providing a voltage-controlled oscillator circuit comprising:
a capacitor electrode;
a capacitor counter-electrode arranged opposite said capacitor electrode at a variable capacitor electrode distance; and
an actuator to vary the capacitor electrode distance, the actuator having an actuator electrode, the actuator electrode being positioned next to an adjacent electrode on a common carrier, the adjacent electrode being the capacitor electrode or the capacitor counter-electrode; and
electrically controlling the actuator electrode to vary the capacitor electrode distance.

35. A method for adjusting impedance, comprising:
providing an impedance-matching circuit comprising:
a capacitor electrode;
a capacitor counter-electrode arranged opposite said capacitor electrode at a variable capacitor electrode distance; and
an actuator to vary the capacitor electrode distance, the actuator having an actuator electrode, the actuator electrode being positioned next to an adjacent electrode on a common carrier, the adjacent electrode being the capacitor electrode or the capacitor counter-electrode; and
electrically controlling the actuator electrode to vary the capacitor electrode distance.
